(19) United States
(12) Patent Application Publication
(10) Pub. No.: US 2011/0141700 A1
(43) Pub. Date: Jun. 16, 2011

(54) HEAT DISSIPATION APPARATUS

(75) Inventors: HENG LIU, Shenzhen City (CN); JIAN YANG, Shenzhen City (CN); JING ZHANG, Shenzhen City (CN)

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 12/752,147

(22) Filed: Apr. 1, 2010

(30) Foreign Application Priority Data
Dec. 15, 2009 (CN) 200910311460.5

(51) Int. Cl. H05K 7/20; F28F 9/00

(52) U.S. Cl. 361/720; 165/67

(57) ABSTRACT

An exemplary heat dissipation apparatus includes a heat sink and fasteners mounting the heat sink on an electronic component on a circuit board. The heat sink includes a thermal conductive core, fins extending outwardly from the thermal conductive core and mounting plates extending outwardly from the thermal conductive core. A mounting arm extends outwardly from each of the mounting plates. The mounting arm defines receiving holes therein. Each fastener passes through a selected one of the receiving holes of a corresponding mounting arm.

### BACKGROUND

1. Technical Field

The present disclosure generally relates to heat dissipation, and particularly to a heat dissipation apparatus for electronic components.

2. Description of Related Art

With developments in technology, increased performance of electronic components such as CPUs (central processing units) has been achieved. However, such electronic components generate increased levels of heat, which must be dissipated promptly. Conventionally, a heat sink is attached to an electronic component to remove the generated heat. The heat sink is attached on a circuit board on which the electronic component is mounted.

The heat sink includes a plurality of mounting arms extending outwardly therefrom. Each of the mounting arms defines a through hole therein. The circuit board defines a plurality of receiving holes therein, corresponding to the through holes of the mounting arms. A fastener, such as a screw, passes through the through hole of each of the mounting arms and is received in a corresponding receiving hole of the circuit board to mount the heat sink on the circuit board. Positions of the receiving holes of the heat sink cannot be changed once the heat sink is manufactured. However, different circuit boards may present different layouts of receiving holes, and a particular heat sink may not be compatible with all such circuit boards. In other words, the adaptability of the heat sink is limited.

Therefore, what is needed is a heat dissipation means which can overcome the described limitations.

### BRIEF DESCRIPTION OF THE DRAWINGS

FIG. 1 is an isometric, assembled view of a heat dissipation apparatus in accordance with an embodiment of the present disclosure.

FIG. 2 is an exploded view of the heat dissipation apparatus of FIG. 1.

FIG. 3 is similar to FIG. 1, but shows the heat dissipation apparatus in a different state.

### DETAILED DESCRIPTION

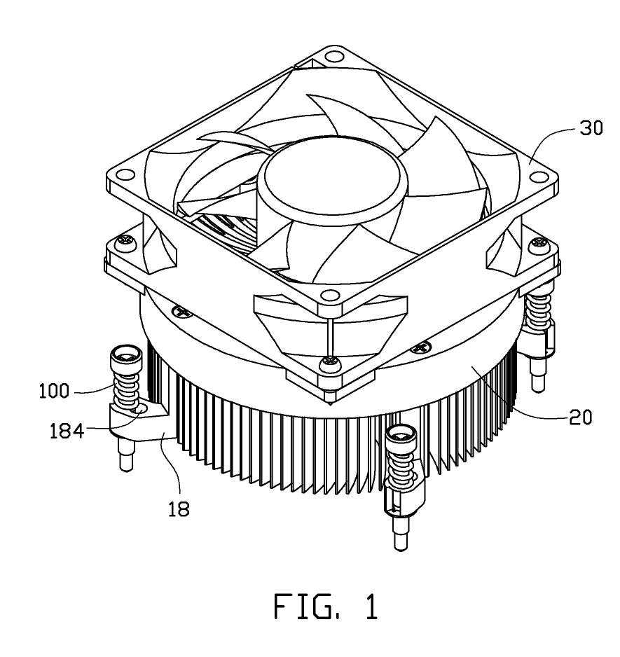

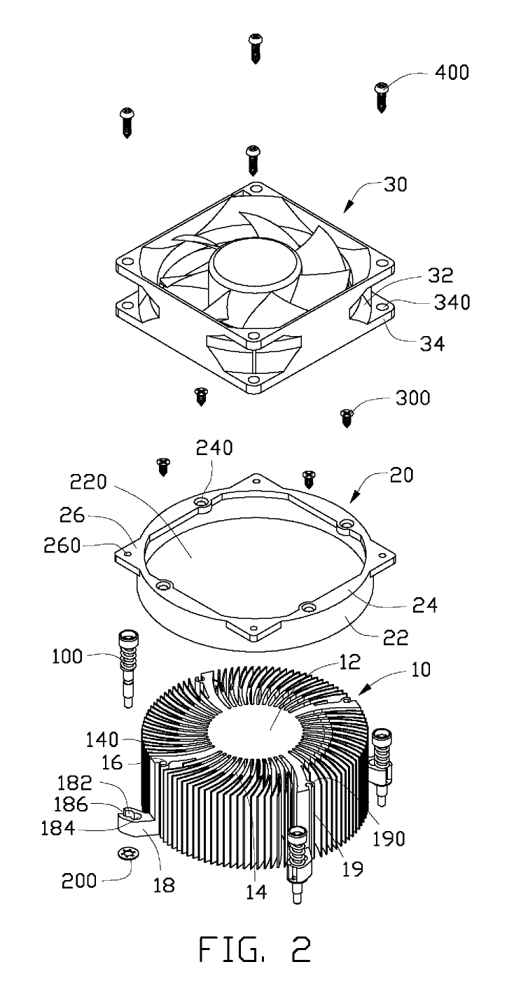

Referring to FIGS. 1 and 2, a heat dissipation apparatus according to an embodiment of the present disclosure is shown. The heat dissipation apparatus is configured for dissipating heat from an electronic component (not shown), such as a CPU (central processing unit) mounted on a circuit board (not shown) of a computer (not shown). The heat dissipation apparatus includes a heat sink 10, a bracket 20 mounted on the heat sink 10, a fan 30 mounted on the bracket 20, and four first fasteners 100 fixing the heat sink 10 on the circuit board on which the electronic component is mounted. The first fasteners 100 are preassembled on the heat sink 10 by a plurality of locking washers 200.

The heat sink 10 has a cylindrical configuration and is formed as an integral structure by extrusion. That is, the heat sink 10 is a single, one-piece, monolithic body without any internal seams. The heat sink 10 includes a cylindrical thermal conductive core 12, a plurality of fins 14 extending generally radially and outwardly from the thermal conductive core 12, and four mounting plates 16 extending generally radially and outwardly from the thermal conductive core 12. The thermal conductive core 12 is attached to the electronic component to absorb heat therefrom. The fins 14 and the mounting plates 16 are integrally formed with the thermal conductive core 12. Each of the fins 14 and each of the mounting plates 16 are curved. The fins 14 are oriented so that their curvatures are uniformly arranged around a circumference of the thermal conductive core 12. The four mounting plates 16 are generally symmetrical relative to the thermal conductive core 12 and evenly spaced from each other. The mounting plates 16 are oriented so that their curvatures match the arrangement of the curvatures of the fins 14. All the fins 14 and all the mounting plates 16 are arranged such that their free ends point in a generally clockwise direction. Each of the fins 14 includes a base portion (not labeled) adjacent to the thermal conductive core 12, and two bifurcated portions 140 integrally branching from the base portion.

The four mounting plates 16 evenly divide the fins 14 into four groups. Each mounting plate 16 is thicker than each fin 14. An open mounting tube 19 is formed at a free end of each of the mounting plates 16. An axis of the mounting tube 19 is parallel to an axis of the thermal conductive core 12. An engaging hole 190 is defined in each of the mounting tubes 19 along the axis thereof.

A mounting arm 18 extends outwardly from a bottom portion of each of the mounting plates 16. Each mounting arm 18 defines a first receiving hole 182 and a second receiving hole 184 therein. The first receiving hole 182 and the second receiving hole 184 are parallel to the axis of the thermal conductive core 12. The first receiving hole 182 and the second receiving hole 184 are juxtaposed side by side and communicate with each other. The second receiving hole 184 is located generally adjacent to free ends of the nearest fins 14, and the first receiving hole 182 is located at an outer side of second receiving hole 184. That is, the first receiving hole 182 is located farther away from the thermal conductive core 12 than the second receiving hole 184. Each mounting arm 18 further defines an opening 186 at an outer free end thereof. The opening 186 of each mounting arm 18 communicates with the first receiving hole 182 of the mounting arm 18. Thus, the first and second receiving holes 182, 184 communicate with the ambient environment at the free end of the mounting arm 18 via the opening 186. The mounting arms 18 can be integrally formed with the heat sink 10 through a single mold.

The bracket 20 includes an annular ring 22, four symmetrical positioning portions 24 extending inwardly from a top edge of the ring 22, and four symmetrical mounting portions 26 extending outwardly from the top edge of the ring 22. The ring 22 defines a ventilating passage 220 therein for receiving a top portion of the heat sink 10. The four positioning portions 24 protrude from the top edge of the ring 22 into the ventilating passage 220 and are evenly spaced from each other. The top portion of the heat sink 10 is blocked by the positioning portions 24 of the bracket 20. Each of the positioning portions 24 defines a through hole 240 therein, corresponding to a respective one of the engaging holes 190 of the heat sink 10. A second fastener 300 can be extended through the through hole 240 and engaged in the engaging hole 190. Thereby, the second fasteners 300 mount the bracket 20 onto the heat sink 10. The four mounting portions 26 are evenly spaced from each other. Each of the mounting portions 26 defines a positioning hole 260 therein.

The fan 30 is aligned with the ventilating passage 220 of the bracket 20. The fan 30 includes a frame 32. The frame 32 has a rectangular configuration, and includes four pairs of corners 34 formed thereon. Two of the pairs of corners 34 are located at a top side of the frame 32, and the other two pairs of corners 34 are located at a bottom side of the frame 32. Each pair of corners 34 at the top side faces one of the pairs of corners 34 at the bottom side. Each of the corners 34 defines a locating hole 340 therein. The locating holes 340 of the corners 34 at the bottom side of the frame 32 correspond to the positioning holes 260 of the bracket 20. A third fastener 400 can be extended through each of such locating holes 340 and engaged in the corresponding positioning hole 260. Thereby, the third fasteners 400 mount the fan 30 on the bracket 20.

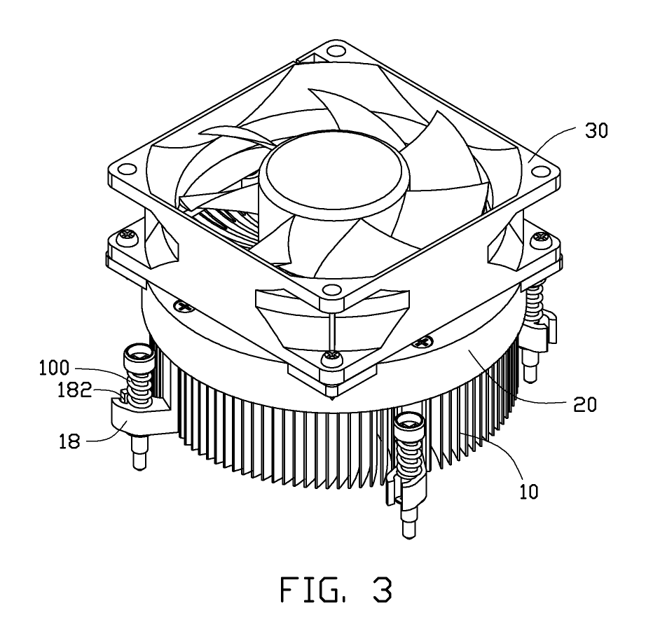

During assembly of the heat dissipation apparatus, the first fasteners 100 are selectively extended through the first receiving holes 182 or the second receiving holes 184 of the heat sink 10, according to need, to mount the heat sink 10 onto a circuit board which has a particular layout. For example, when the circuit board is an INTEL-LGA1156 computer mainboard (not shown), the first fasteners 100 are extended through the first receiving holes 182 of the heat sink 10 to mount the heat sink 10 onto the INTEL-LGA1156 mainboard, as shown in FIG. 1. When the circuit board is an INTEL-LGA775 computer mainboard (not shown), the first fasteners 100 are extended through the second receiving holes 184 of the heat sink 10 to mount the heat sink 10 onto the INTEL-LGA775 mainboard, as shown in FIG. 3.

The heat dissipation apparatus is compatible with different circuit boards having different layouts. Thus the adaptability of the heat dissipation apparatus is enhanced.

Though just a first receiving hole 182 and a second receiving hole 184 are defined in each mounting arm 18 of the heat sink 10 in the foregoing embodiment, it should be noted that a third receiving hole (not shown) can be defined or integrally formed in each mounting arm 18 of the heat sink 10 to enable the heat dissipation apparatus to be compatible with an increased range of circuit board layouts. In still other alternative embodiments, there can be a total of four or even more receiving holes in each mounting arm 18 of the heat sink 10.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat dissipation apparatus for an electronic component mounted on a circuit board, the heat dissipation apparatus comprising:
a heat sink comprising a thermal conductive core from which a plurality of fins and a plurality of mounting plates extend outwardly, each of the mounting plates comprising a mounting arm protruding outwardly therefrom, each mounting arm defining at least two receiving holes therein; and
a plurality of fasteners mounting the heat sink on the circuit board, each of the fasteners passing through a selected one of the at least two receiving holes of a corresponding mounting arm.

2. The heat dissipation apparatus of claim 1, wherein the at least two receiving holes are juxtaposed side by side and communicate with each other.

3. The heat dissipation apparatus of claim 2, wherein the at least two receiving holes of each mounting arm are arranged such that one of the receiving holes is located farther from the thermal conductive core than another of the receiving holes.

4. The heat dissipation apparatus of claim 3, wherein the mounting arm defines an opening at an outer side thereof, the opening communicating with at least one of the receiving holes.

5. The heat dissipation apparatus of claim 1, wherein each of the mounting arms protrudes outwardly from a bottom portion of the mounting plate.

6. The heat dissipation apparatus of claim 1, wherein the mounting plates extend generally radially outwardly from the thermal conductive core, the mounting plates are evenly arranged around the thermal conductive core, and the fins are separated by the mounting plates but otherwise evenly arranged around the thermal conductive core.

7. The heat dissipation apparatus of claim 6, wherein each of the fins and each of the mounting plates is curved, and the fins and the mounting plates are oriented so that their curvatures are uniformly arranged around a circumference of the thermal conductive core, with free ends of all the fins and all the mounting plates pointing in a generally clockwise direction.

8. The heat dissipation apparatus of claim 1, further comprising a bracket and a fan mounted on the bracket.

9. The heat dissipation apparatus of claim 8, further comprising another plurality of fasteners, wherein an open mounting tube is formed at a free end of each of the mounting plates, and each of the another plurality of fasteners is configured for passing through the bracket and engaging in a corresponding one of the mounting tubes thereby mounting the bracket on the heat sink.

10. The heat dissipation apparatus of claim 1, wherein the heat sink is a single, one-piece, monolithic body.

11. A heat dissipation apparatus for an electronic component mounted on a circuit board, the heat dissipation apparatus comprising:
a heat sink comprising a plurality of fins and a plurality of mounting arms around the fins, each mounting arm defining a first receiving hole and a second receiving hole therein; and
a plurality of fasteners attached to the plurality of mounting arms, respectively, the heat sink being capable of being mounted by the fasteners in a selected one of first and second mounting states, wherein in the first mounting state, the fasteners pass through the first receiving holes of the mounting arms, and in the second mounting state, the fasteners pass through the second receiving holes of the mounting arms.

12. The heat dissipation apparatus of claim 11, wherein the first and second receiving holes of each mounting arm are juxtaposed side by side.

13. The heat dissipation apparatus of claim 12, wherein the first and second receiving holes of each mounting arm communicate with each other.

14. The heat dissipation apparatus of claim 11, further comprising a plurality of mounting plates, wherein the heat sink comprises a cylindrical central core, from which the fins and the mounting plates respectively extend generally radially outwardly, each of the mounting plates being thicker than each of the fins, with the mounting arms extending from the mounting plates, respectively.

15. The heat dissipation apparatus of claim 13, wherein each mounting arm is formed at an outer, bottom corner of a corresponding mounting plate.
